(19) United States
(12) Patent Application Publication
(10) Pub. No.: US 2009/0090992 A1
(43) Pub. Date: Apr. 9, 2009

(54) ISOLATION TRENCH STRUCTURE FOR HIGH ELECTRIC STRENGTH

(75) Inventors: Ralf Lerner, Erfurt (DE); Uwe Eckoldt, Hohenfelden (DE)

Correspondence Address: STEVENS & SHOWALTER LLP, 7019 CORPORATE WAY, DAYTON, OH, 45459-4238, US

(73) Assignee: X-FAB SEMICONDUCTOR FOUNDRIES AG, Erfurt (DE)

(21) Appl. No.: 12/096,661

(22) PCT Filed: Dec. 8, 2006
(86) PCT No.: PCT/EP06/69475

§ 371 Date: Oct. 31, 2008

(30) Foreign Application Priority Data
Dec. 10, 2005 (DE) 10 2005 059 035.7

(51) Int. Cl. H01L 29/06; H01L 21/762

(52) U.S. Cl. 257/506; 438/424; 257/E29.02; 257/E21.546

(57) ABSTRACT

The invention relates to an isolation trench structure and a corresponding layout wherein the insulating properties of isolation trenches (10, 10′) in critical areas (at intersections and junctions) are improved. Flattened and/or rounded off corner areas (10a, 10b) of the semiconductor regions to be insulated are produced, the etching and filling behavior being adjusted to be similar to that in the areas outside the critical areas, a center island (18, 18′) being provided for adapting the effective trench width in the critical areas of transition. The isolation trench structure is suitable for semiconductor arrangements (smart power applications) in which large voltage differences occur between the regions (12, 12′) to be electrically insulated from each other and the corresponding components. Power components can be integrated on the same chip together with small-signal elements.

The invention relates to isolation trenches (trenches) having a high aspect ratio for trench isolated semiconductor regions, for instance for smart power technology, in particular for Silicon On Insulator (SOI) silicon wafers, wherein the insulating behaviour is enhanced, the error rate is reduced and the manufacturing process is simplified by a geometric design (layout) of the intersection and/or junction areas of isolation trenches. The insulating behaviour is to be understood as the electric insulation, which may also be referred to as electric strength.

Isolation trenches in semiconductor carrier materials, for instance in SOI silicon wafers, are used to isolate different devices (for instance transistors) or entire regions with respect to each other in integrated circuits, in particular in smart power circuits, so as to make them appropriate for different potentials. In this case, the isolation trench may circularly surround for instance the device to be insulated or the region to be insulated, as is described in U.S. Pat. No. 5,734,192 or also in U.S. Pat. No. 6,394,638.

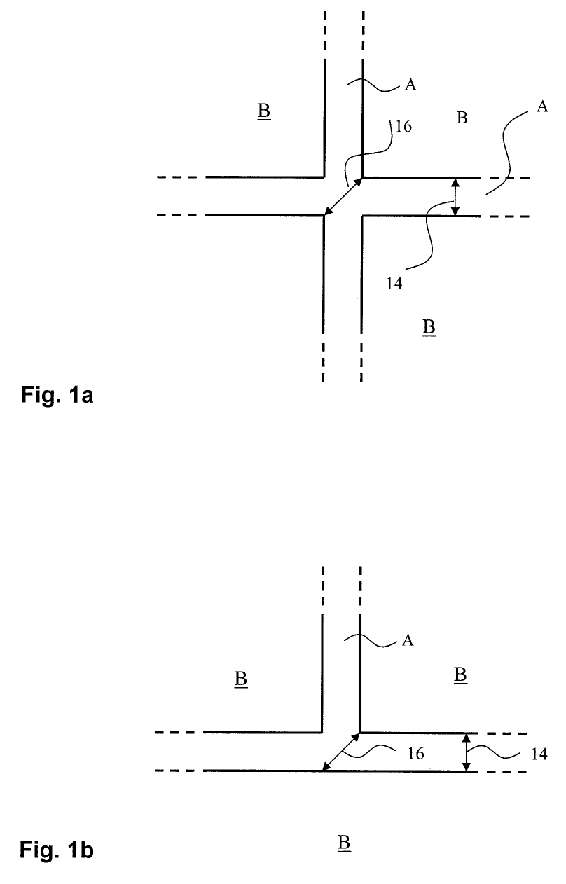

Furthermore, U.S. Pat. No. 5,283,461 discloses a trench structure in which the devices to be insulated are separated by a network of isolation trenches, cf. FIG. 1, which illustrates intersections (FIG. 1a) and T-shaped conjunctions or junctions (FIG. 1b) of isolation trenches.

In FIG. 1a and FIG. 1b a top view of an active silicon layer 12 is illustrated in which an isolation trench A having a breadth or width 14 is formed such that the isolation trench is enclosed on both sides thereof by a region B of an active silicon layer of the wafer. At the intersections or junction areas a diagonal width 16 of the isolation trench is obtained. In this case, the diagonal width 16 at the intersection is significantly greater than the width 14 of the single linearly extending isolation trench A. In the example shown the width 16 is approximately 1.4 times the width 14 for both the intersection in FIG. 1a and the junction of FIG. 1b. U.S. Pat. No. 6,524,928 exemplarily describes the structure of the isolation trench A.

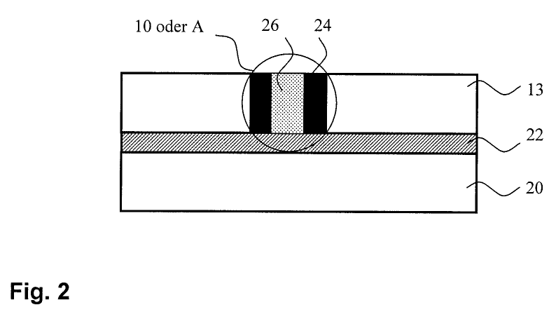

FIG. 2 of this application schematically illustrates a cross-sectional view of the isolation trench A in an SOI substrate. The base material is the SOI wafer that consists of a carrier wafer, i.e. the substrate 20, the active silicon layer 13 and a buried oxide 22, which isolates the carrier wafer 20 from the silicon layer 13 used for the active devices. Initially, an insulation layer 24, for instance a dielectric material such as silicon dioxide, is formed on sidewalls of the etched isolation trench 10. Subsequently, the isolation trench is filled with a fill material 26, for instance polysilicon, and is planarized.

The deposition of the fill layer 26 for filling the isolation trench is accomplished by, for instance, chemical or physical deposition techniques (CVD or PVD processes). Since a respective isolation trench is coated from both sides (flanks) during the deposition of the fill layer 26, theoretically a layer thickness of at least half of the width 14 is required so as to fill the linear isolation trench (outside of the intersections). For a complete filling of the entire isolation trench system, however, this is not sufficient since for a complete filling also the intersection or junction and thus the width 16 has to be taken into consideration. The layer thickness required therefore is thus at least half of the width 16 and is thus significantly greater than the layer thickness that would be required for filling the trench width 14. An increased layer thickness, however, means longer process times and thus an increased error rate and process costs.

Providing an overall reduced width of the isolation trench system for reducing the deposition time is, however, typically not an appropriate approach. On the one hand, partly certain dimensions are to be maintained, and on the other hand a certain aspect ratio and thus, for a given thickness of the active silicon layer, a certain width of the isolating trench is required for a stable etch process for the isolating trench. Hence, the requirement for a minimum deposition time cannot be fulfilled by simply reducing the width 14 of the isolation trench.

A further problem in conventional isolation trenches resides in the fact that at 90° intersections and junctions (so-called transition locations or areas) of the isolation trenches acute edges may form that possibly result in electric breakthroughs at high voltages to be insulated. Instead of an acute edge, also “sharp edge” (at the corner) may be used as a corresponding term.

U.S. Pat. No. 6,335,260 (Tseng) discloses an isolation trench in which the filling in of polysilicon is enhanced at junctions by reducing the width at a junction location by a triangular or semicircular configuration of the region to be isolated in the junction area of the isolation trenches, cf. col. 7, lines 25 to 28 and FIG. 7 with reference number 704. The problem of intersections is, however, not addressed therein.

U.S. Pat. No. 5,072,266 (Bulucea et al.) describes a power MOSFET wherein the electric strength of the gate is increased by confining the gate by means of an isolation trench provided in the form of a polygon, for instance a hexagon. With respect to the problem of efficiently filling the isolation trenches this document does not provide any advice.

It is an object of the invention to provide a structure of isolation trenches resulting in a reduction of the sharpness of the edges at the corners of the trench walls and providing a substantially homogeneous isolation trench width even at intersections or junction areas. The trenches should be filled in a void-free manner with as low an effort as possible during the deposition of the fill layer.

The object is solved by the features defined in claims 1, 6, 12 and 13. The layout method is covered by claim 15.

According to one aspect an isolation trench structure is provided in a semiconductor device assembly including isolation trenches that form an intersection area or a junction area. The isolation trenches define and isolate regions from each other that have flattened or rounded corners in the intersection area and/or junction area. Furthermore, a middle island is located in the intersection area or in the junction area so as to adapt a width of the isolation trenches in the intersection area or junction area with respect to a width of the isolation trenches outside of the intersection area and/or junction area.

By providing the middle island in the intersection area or the junction area an expansion of the effective trench width (breadth) can be reduced. The expansion would be particularly pronounced without the middle island. Due to the presence of edges that are no longer acute (no longer sharp) at the corners in the critical intersections or junctions an even more pronounced expansion would result, which however is avoided by the middle island.

In this manner, a design for isolation trenches is provided, which reduces the edge sharpness (acuteness of the edges) of the corners at the intersection and junction locations of the isolation trenches and provides an adapted trench width in the transition area of the trenches so as to enable the filling of the trench with a substantial identical and small layer thickness, that is, with short a deposition time as possible and thus at a reduced error rate and costs. The “flattening” of the corners, i.e. rounding or flat portion, is described such that no acute corners (no sharp edges) are present in the transition area. As such transition area a junction (at least three trenches) or an intersection is to be understood (at least four trenches). Less than three trenches, i.e. an angled configuration of a continuous trench, should not be enclosed herein. Hence, at the junction or intersection of the first trenches a transition zone (as such an “area”) is created, in which the connecting trenches provide for the insulation and connect respective two oppositely extending first trenches. In this manner, the neighbouring regions for the devices, for instance high voltage above 100 V and low voltage below 50V, may remain insulated from each other.

The invention also provides an enhancement of the insulating effect of the isolation trenches with respect to high voltages while concurrently reducing the width of the isolation trenches at the intersection and junction locations to the predetermined width of the linear isolation trench outside of these locations. A sharpness of edges at the acute corners of the trench walls is reduced by the flattening, whereby the insulating effect is enhanced for higher voltages and a disadvantageous expansion of the isolation trenches in the transition area is avoided.

The flattened corners (the regions to be insulated form an angle of more than 90° with the isolation trenches) result in a significant reduction of the corresponding field strengths in the trench, thereby providing advantages in applications involving very different potentials of the individual regions to be insulated, wherein however simple layout configurations may be applied, for instance in the form of linear edge structures having respective large angles, for instance greater than 90° or greater than 130°. In this case also the middle island may be flattened in a highly efficient manner, since also corresponding edge structures in the middle island may be provided. In this way, already in the layout effective geometric configurations may be used, wherein a corresponding rounding during the actual patterning of the isolation trenches by photolithography and etching may not necessarily be performed, if desired.

According to a further aspect the non-sharp/non-acute corner regions are each rounded in the transition area that is defined by the merging isolation trenches, for instance, already at designing of a corresponding layout pattern so that additionally the insulating characteristics may be improved in a highly efficient manner.

In a further preferred embodiment areas adapted to the rounding are provided in the middle island, for instance at least sections in the form of convex outer surfaces so that even at the roundings a reduced width of the connecting isolation trenches is achieved, which may thus correspond to substantially the width of the trenches outside of the intersections or junctions (as transition areas).

According to a further aspect appropriate layout patterns for isolation trenches are provided, which allow the fabrication of trenches and comprise already inherently in the layout structure the improvement with respect to the fill characteristics and the insulating characteristics such that process-dependent factors have a reduced influence and thus allow increased flexibility when establishing the processes.

The middle island physically contacts the edges of the regions to be insulated via the filling of the connecting trenches in the transition area only. Such a configuration of an island is to be considered as a real island, i.e. entirely enclosed by the fill substance in the isolating trenches.

Preferred embodiments are also set forth in the following description.

Embodiments of the invention will now be described by way of illustrative embodiments while also referring to the drawings.

The description comprises the following drawings, throughout which like or similar components are denoted by the same reference signs. Examples of the invention are described.

FIG. 1a, 1b schematically illustrate top views of a usual isolation trench structure comprising an intersection (FIG. 1a) and a junction (FIG. 1b), respectively.

FIG. 2 schematically illustrates a cross-section through a conventional trench structure as may also be used, in a filled state, for the following examples.

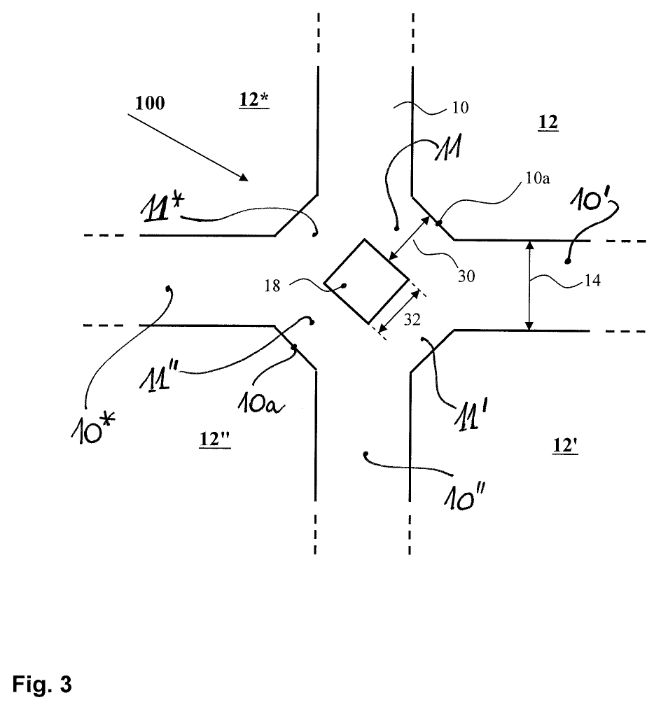

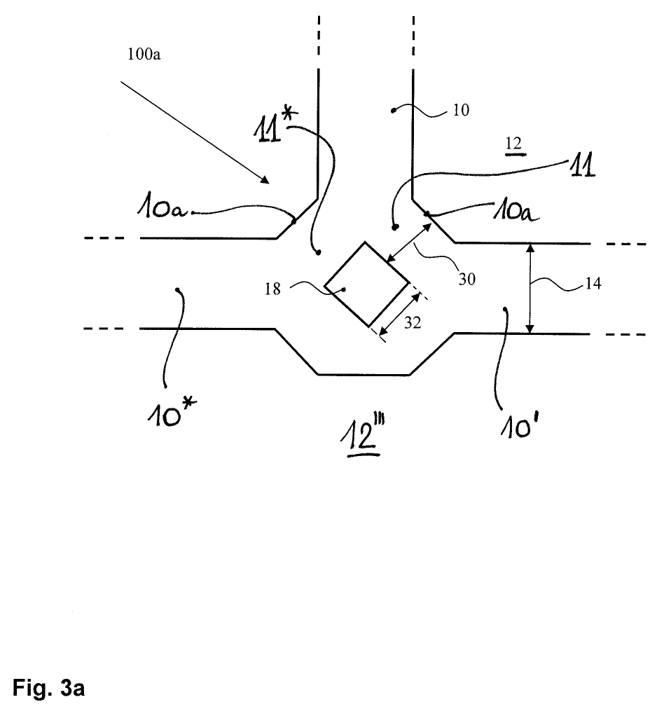

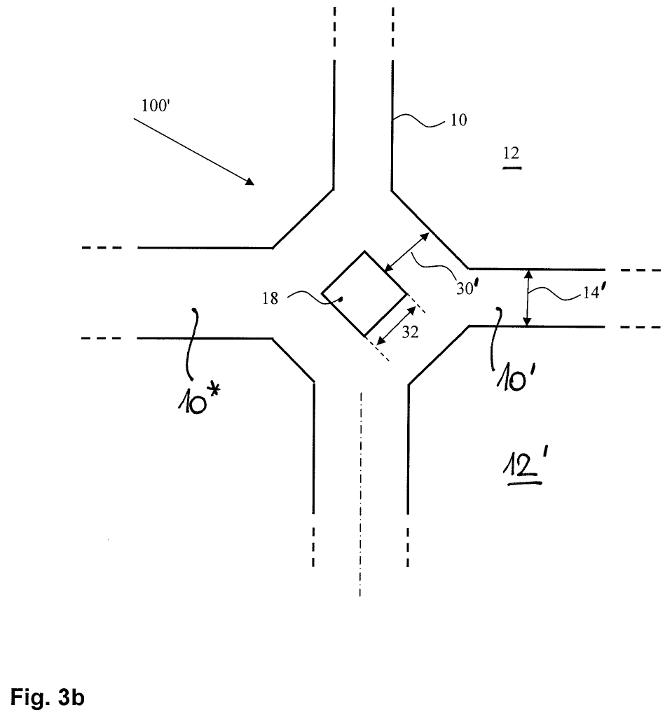

FIG. 3 illustrates a top view of a 90° intersection of isolation trenches in a schematic view corresponding to a first example of the invention.

FIG. 3a schematically illustrates the top view of a junction comprising a middle island.

FIG. 3b schematically illustrates a 90° intersection in which the trench widths 14′, 30′ in the intersection area are substantially equal to the width 14′ of the trenches outside of the intersection area.

FIG. 3c corresponds to FIG. 3b with an illustration of the width 14′, 30′ that is more true to scale.

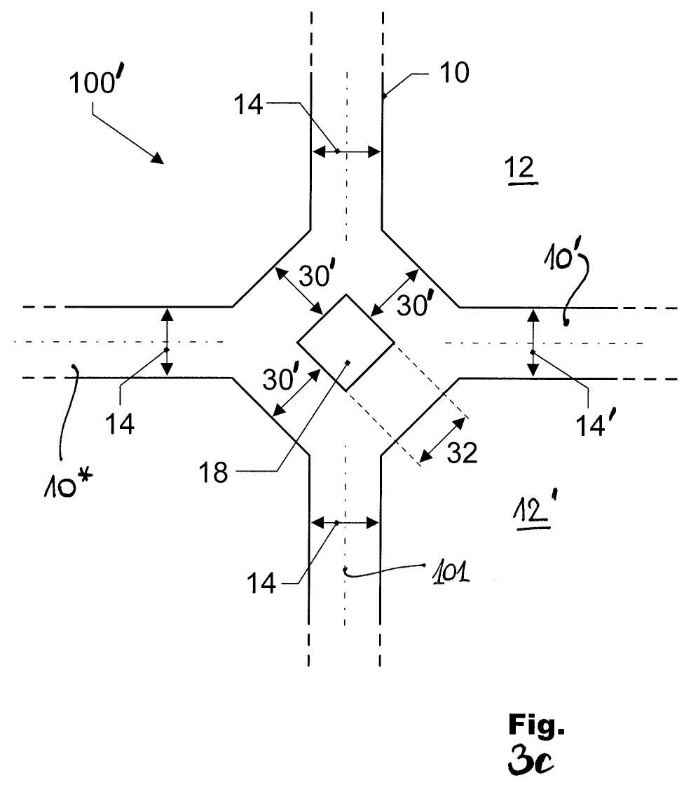

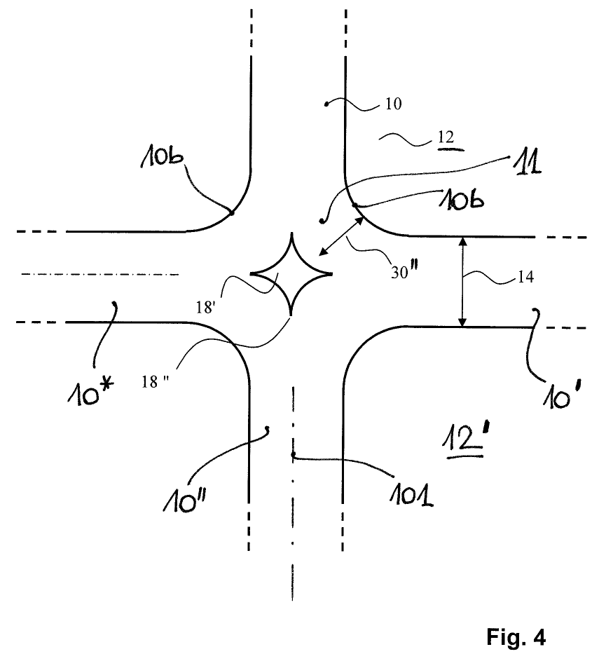

FIG. 4 illustrates a further variant as in FIG. 3, comprising rounded corners.

As shown in FIG. 3 a trench isolation structure comprises the isolation trenches 10, 10′, 10″ und 10* which define and mutually insulate the regions 12, 12′ und 12* when the isolation trenches are realized in a semiconductor device assembly. In the illustration shown the isolation trenches may represent the layout, for instance the pattern of a photomask used for patterning actual trenches, or may represent a schematic configuration of real structures. The filling of the trenches may be accomplished according to FIG. 2.

In an intersection area 100 of the four isolation trenches flattened corner areas 10a are provided and in the middle of the intersection location or the intersection area 100 a middle island 18 having an appropriate edge length 32 is maintained. In the example illustrated a 90° intersection is formed, wherein however also other intersection angles may be used. The sharp or acute 90° angle that is present is “relaxed” by providing the flattened corner areas 10a so that the regions 12, 12′ form angles with the respective inner isolation trench sections 11, 11′ at the edge, wherein these angles are significantly greater than 90° and are preferably greater than 130°. Moreover, the width 30 within the intersection 100 is adapted more efficiently to the width 14 such that enhanced fill behaviour is obtained, as is explained above. In this case, the width 30 may be somewhat greater and may be substantially equal to or also less, as is shown here, as long as the required process reliability during the patterning of the intersection area 100 is ensured for a given width 30 that is less than the width 14. The ratio is significantly less than 1.4 when relating the inner width 30 of the connecting trenches 11, 11′, 11″ and 11* to the width 30 of the trenches 10, 10′, 10″ and 10* outside of the transition area 100, here in the form of an intersection area.

In the embodiment shown a middle island 18 is used, which is rotated by 45° with its linear edges with respect to the linear sidewalls of the isolation trenches. Therefore, the actual isolation trenches 10 do not have any 90° corners at the intersection location 100, but have a bevel with 135° angles of the regions 12, 12′ and the like, which may for instance represent an active silicon layer of an SOI substrate. In this manner, the 90° corners that are critical for high voltage applications are not present.

Moreover, isolation trenches may be used that may merge with other angles than 90° or which are intersecting and which are combined with a respective middle island 18 that is adapted accordingly. Also this island is completely surrounded by trenches 11 and the like.

FIG. 3a illustrates an embodiment in which a junction 100a is illustrated wherein a middle island 18′ has a similar configuration as the island in FIG. 3. Also in this embodiment an undesired strong expansion of the isolation trenches 10, 10′, 10″ in the junction 100a may substantially be avoided, wherein similar patterning conditions as are encountered for the intersection 100 in FIG. 3 may also be obtained for the junction 100a in FIG. 3a, since identical dimensions may be used for the middle island. The connecting trenches 11, 11* are at least approximated to the width/breadth 14 of the outer trenches 10, 10′, 10*.

In other examples the dimensions and/or the shape of the middle island 18′ for the junction of FIG. 3a may differ from the corresponding dimensions and/or shape of the middle island 18 for the intersection of FIG. 3, for instance the island 18 may be formed as a triangle that is completely surrounded by trenches, wherein the hypotenuse is adjacent to the region 12′″, facing thereto and being spaced apart therefrom.

FIG. 3b schematically illustrates a further 90° intersection 100′, in which the trench side 30′ substantially corresponds to the width 14′, as in FIG. 3c, more true to scale (widths 14′, 30′). In the illustrated example the width or breadth 30′ is adapted to the width or breadth 14′ of the isolation trench to be filled and this leads to a uniform filling of the trench in the intersection area. Hence, also in the intersection area 100′ approximately the same patterning conditions are achieved as in areas outside.

FIG. 4 illustrates a further embodiment in which “corners” 10b of the regions 12 are flattened so that already no sharp edges occur in the layout, wherein the middle island 18′ provides for a reduced trench width in the transition area 100″, as is described above. Moreover, in the embodiment illustrated, contrary to the rounded corners 10b (convex corners) of the areas 12, 12′ to be insulated from each other concave roundings are provided, that is, concave outer surfaces or sidewall sections (flanks) of the island 18′ so that a relatively constant width 30″ of the isolation trenches 11 is obtained even in the area of the roundings.

The apexes 18″ of the ends of the concave areas substantially point to the middle 101 of the isolation trenches extending from the outside, for instance 10″.

Further embodiments relate to an SOI isolation trench structure in the intersection and junction area of isolation trenches (layout) of semiconductor device assemblies, which electrically insulate regions 12 including devices of high electric voltage with respect to neighboring regions by means of the isolation trenches 10, 10′.

High voltages are higher than 100V, regions 12′ comprising devices or used for devices of low voltage are provided for no more than 50V so as to assign a meaning to the terms high voltage/low voltage that does not deviate from the standard terminology.

The corners of the regions 12 to be insulated from each other are flattened in the intersection and junction area, respectively, and in the centre of the intersection area or the junction area a middle island is provided of the same material as the region 12, however unprocessed, which island is adapted in its shape to the contour of the flattened corner such that a sort of transition trench is formed from one isolation trench 10 to another one 10′, which has substantially the same width 30 as the isolation trenches 10. These “transition trenches” are the inner connecting trenches of the outer isolation trenches. Inside and outside, respectively, relates to the transition area, or the outside thereof.

In a further variant of the preceding embodiment the corners of the regions 12 to be insulated are rounded in the intersection and junction area and the middle island 18′ has a concave edge or surface portions that are opposite to the (convex) roundings. The concave flanks are configured to merge in apexes 18″ that are pointing towards the centre of the outer isolation trenches, for example a centre line 101 of the trench 10″.

Each of the examples provide isolation trench structure and also a corresponding layout (also in the form of a method) in which the insulating characteristics of isolation trenches in critical areas (at intersections and junctions) are enhanced by reducing flattened and/or rounded corner areas of the semiconductor regions to be insulated, wherein the etch and fill behavior is adjusted similarly as to the areas outside of the critical areas by providing a middle island for adapting (at least for significantly reducing) the effective trench width in the critical areas.

In this way, the isolation trench structure is particularly appropriate for semiconductor device assemblies in which high voltage differences between the devices to be insulated are encountered, such as smart power applications, in which power devices are integrated into the same chip together with small signal elements. Corresponding aspect ratios of trenches having this electric strength are greater than 4:1, for example, a trench width of more than 3 μm and a trench depth of more than 40 μm or 50 μm.

The isolation trenches typically have an aspect ratio of greater than 4:1, in particular of greater than 10:1 and even more preferable in a range of approximately 15:1. In an embodiment relating to a range between 16:1 and 17:1 the width is approximately 3 μm and the depth is approximately 50 μm. The illustrations in the Figures are thus not to be considered as being true to scale.

### LIST OF REFERENCE SIGNS

10: isolation trench
10a: rounded corner 10b: rounding of the corner
13: active silicon layer (region)
14: width of a single isolation trench 10′
16: diagonal width of the isolation trenches in the intersection location of several isolation trenches
11: transition trench (connecting isolation trench in the transition area)
18: middle island
18′: further middle island
20: carrier wafer/substrate
22: buried oxide
24: insulation layer
26: fill layer
30: width of the isolation trench 11 between active silicon layer 12 and middle island 18
32: edge length of the middle island 18
100: intersection area
100a: junction area
100, 100a: transition area
10′, 10″, 10*: further isolation trenches
11′,11″,11*: connecting trenches in the transition area
12,12′,12″,12*: regions electrically insulated from each other
100′, 100″: further intersection areas

1. An isolation trench structure in a semiconductor device assembly comprising:
first isolation trenches, forming one of an intersection area and a junction area;
first regions defined by the first isolation trenches and insulated from each other by a first width of the first isolation trenches and comprising non-acute or non-sharp corners in the one of an intersection area and a junction area as a transition area; and
a middle island positioned in the transition area for adapting a second width of connecting second isolation trenches in the transition area relative to the first width of the first isolation trenches outside of the transition area.

2. The isolation trench structure of claim 1, wherein the middle island is adapted in its edge shape to a contour of the non-acute or non-sharp corners such that the width of the second isolation trenches in the transition area is at least approximately equal to the width of the first isolation trenches outside of the transition area.

3. The isolation trench structure of claim 1, wherein at least one of the non-acute or non-sharp corners are flattened, and the adaptation of the width is at least an approximation.

4. The isolation trench structure of claim 3, wherein the non-acute or non-sharp corners are formed with an angle of greater than 130°.

5. The isolation trench structure of claim 1, wherein the middle island is made of the same base material as the first regions and is non-processed at the surface of the middle island.

6. An isolation trench structure in a semiconductor device assembly comprising:
isolation trenches forming one of an intersection area and a junction area as a transition area;
regions defined by the isolation trenches and being insulated from each other and comprising rounded corner areas in at least one of the intersection areas and the junction area; and
a middle island positioned in the transition area for adapting a width of isolation trenches in the transition area in relation to a width of the isolation trenches outside of the transition area.

7. The isolation trench structure of claim 6, wherein the middle island is adapted in its shape to the contour of the rounded corner areas such that the widths of the isolation trenches in the transition area are approximately equal to the widths of the isolation trenches outside of the transition area.

8. The isolation trench structure of claim 6, wherein the isolation trench structure is formed to a buried insulating layer.

9. The isolation trench structure of claim 6, wherein the middle island is at least one of formed of the same base material as the regions and non-processed.

10. The isolation trench structure of claim 6, wherein the middle island comprises concave edge portions facing the rounded corner areas.

11. The isolation trench structure of claim 6, wherein concave edge portions of the middle island converge in apexes that point substantially to the corresponding centre of the isolation trenches outside of the transition area.

12. An SOI isolation trench structure comprising one of an intersection and junction area of a plurality of isolation trenches of a semiconductor device assembly, wherein at least a first region including devices for high electric voltage is electrically insulated from second neighbouring regions by the isolation trenches wherein:
corners of the first and second regions to be insulated from each other are substantially flattened in the intersection and junction area and a middle island of the same material as in the first region is provided in the centre of one of the intersection and junction areas of the isolation trenches in a non-processed state, which middle island is adapted in its shape to a contour of the corners such that a transition trench is formed from an isolation trench to another one, which transition trench has at least substantially the same width as the isolation trenches.

13. An SOI isolation trench structure in the intersection and junction area of isolation trenches of a semiconductor device assembly, which electrically insulates regions including devices of high electric voltage from neighbouring regions by the isolation trenches, wherein:
the corners of the regions to be insulated from each other are rounded in the intersection and junction area and a middle island of the same material as in the region is provided non-processed in the centre of the intersection and junction area of the isolation trenches, which middle island is adapted in its shape to the contour of the rounded corner such that a transition trench is formed from one isolation trench to another one which transition trench is approximately of the same width as the isolation trenches.

14. The SOI isolation trench structure of claim 13, wherein the middle island comprises concave area portions which face roundings of the rounded corners, and wherein the concave flanks or area portions merge in apexes that point to the respective centre of the isolation trenches.

15. A method for patterning an isolation trench structure comprising:
forming first isolation trenches comprising one of an intersection area and a junction area;
forming regions defined by the first isolation trenches and insulated from each other by a first width of the first isolation trenches and comprising non-acute or non-sharp corners in the one of an intersection area and a junction area as a transition area; and
forming a middle island positioned in the transition area for adapting a second width of connecting second isolation trenches in the transition area relative to the first width of the first isolation trenches outside of the transition area.

16. The isolation trench structure of claim 1, wherein the isolation trench structure is formed up to a buried insulating layer.

17. The isolation trench structure of claim 1, wherein one of the regions comprises at least a device for voltages higher than 100V, and wherein a further adjacent region comprises a device for voltages below 50V.

18. The isolation trench structure of claim 1, wherein the second isolation trenches form transition trenches having substantially the same width as respective two isolation trenches that are each connected by a transition trench in the transition area.

19. The isolation trench structure of claim 1, wherein the first and second isolation trenches have an aspect ratio of at least 4:1 to 17:1.

20. The isolation trench structure of claim 1, wherein the isolation trench structure is formed in an SOI silicon wafer.

21. The isolation trench structure of claim 1, wherein the connecting second isolation trenches are connecting trenches.

22. The isolation trench structure of claim 3, wherein the non-acute or non-sharp corners are formed with an angle of greater than 90°.
